(19) United States
(12) Patent Application Publication
(10) Pub. No.: US 2026/0117066 A1
(43) Pub. Date: Apr. 30, 2026

(54) RESIN COMPOSITION AND ARTICLE MADE THEREFROM

(71) Applicant: ELITE MATERIAL CO., LTD., Taoyuan City (TW)

(72) Inventor: Chen-Yu HSIEH, Taoyuan City (TW)

(73) Assignee: ELITE MATERIAL CO., LTD., Taoyuan City (TW)

(21) Appl. No.: 19/010,809

(22) Filed: Jan. 6, 2025

(30) Foreign Application Priority Data
Oct. 30, 2024 (TW) 113141433

(51) Int. Cl. C08L 71/12; C08J 5/24; C08L 15/00; C08L 65/02; H05K 1/03

(52) U.S. Cl. CPC C08L 71/126; C08J 5/244; C08L 15/00; C08L 65/02; C08J 2315/00; C08J 2365/02; C08J 2371/12; C08J 2425/18; C08J 2435/02; H05K 1/0373; H05K 2201/012

(57) ABSTRACT

The present disclosure provides a resin composition, including a vinyl group-containing resin and a phosphorus-containing copolymer. The phosphorus-containing copolymer is polymerized from a monomer represented by Formula (1) and a monomer represented by Formula (2). Further, the present disclosure also provides an article made from the aforesaid resin composition, including a prepreg, a resin film, a laminate, or a printed circuit board.

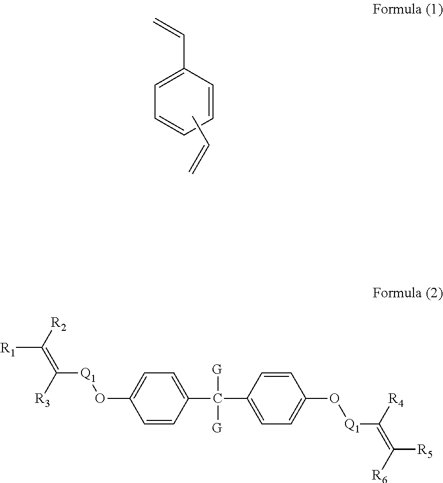

### CROSS-REFERENCE TO RELATED APPLICATIONS

This non-provisional application claims priority under 35 U.S.C. § 119 (a) on patent application No. 113141433 filed in ROC on Oct. 30, 2024, the entire contents of which are hereby incorporated by reference.

### BACKGROUND

### 1. Technical Field

The present disclosure relates to a resin composition and an article made therefrom, particularly to a resin composition that can be used for a prepreg, a resin film, a laminate, or a printed circuit board.

### 2. Related Art

Recently, with the rapid development of the information industry, electronic products have become increasingly small, lightweight, high-performance and multifunctional. Printed circuit boards serve as basic components of various electronic products and play an important role in supporting and conducting electronic elements thereon. Therefore, in order to meet the constantly upgrading demands of various electronic products, resin compositions for manufacturing printed circuit boards have become a hot research topic.

Currently, printed circuit boards or related articles made from resin compositions still have room for improvement in dissipation factor, copper foil peeling strength, flame retardancy and X-axis coefficient of thermal expansion. Therefore, how to improve the above properties of resin compositions is a development direction in this field.

### SUMMARY

In view of the above problems in the prior arts, specifically, the current material is unable to meet the technical demands, the main purpose of the present disclosure is to provide a resin composition and an article made from the resin composition to solve at least one of the above problems.

One exemplary embodiment of the present disclosure provides a resin composition, including:
a vinyl group-containing resin; and
a phosphorus-containing copolymer, polymerized from a monomer represented by Formula (1) and a monomer represented by Formula (2);

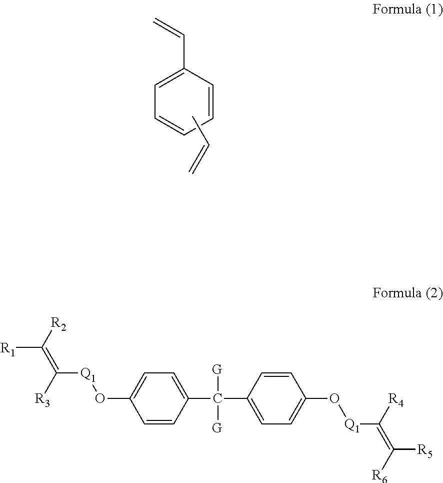

wherein each of R₁ to R₆ is independently selected from a hydrogen or a C1-C3 alkyl group;
wherein each G independently represents any one of a group represented by Formula (3) or a group represented by Formula (4) which is a monovalent phosphorus-containing functional group;

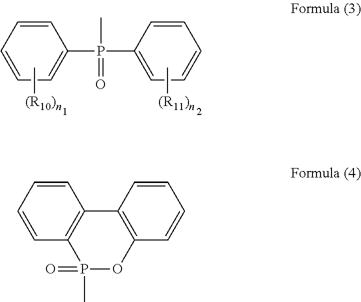

wherein each of R₇ to R₈ is independently a C1-C3 alkyl group, and each of n₁ to n₂ is independently an integer of 0 to 3;
wherein each Q1 independently represents any one of —CO— or *—CH₂—C₆H₄-which is a divalent functional group, and a symbol “*” represents a binding site which binds to an oxygen atom.

Another exemplary embodiment of the present disclosure provides an article made from the resin composition, including a prepreg, a resin film, a laminate, or a printed circuit board.

The article, such as a prepreg, a resin film, a laminate, or a printed circuit board, made from the resin composition of the present disclosure has an excellent performance in at least one of the dissipation factor, the copper foil peeling strength, the flame retardancy and the X-axis coefficient of thermal expansion. Therefore, the article can be served as a high-performance laminate that satisfies the comprehensive demands.

### DETAILED DESCRIPTION

Unless otherwise specified, the term “monomer” used herein refers to a molecule that can be covalently linked to the same or other molecules to form a polymer.

Unless otherwise specified, the term “polymer” used herein refers to products formed by monomer(s) via polymerization. A polymer may include a homopolymer, a copolymer, a prepolymer, etc., but the present disclosure is not limited thereto. A prepolymer refers to a chemical substance formed by monomer(s) via polymerization with a conversion rate between 10% and 90%. A polymer includes an oligomer, but the present disclosure is not limited thereto. An oligomer, also known as low polymer, refers to a polymer formed by 2 to 20, typically 2 to 5, repeating units. For instance, diene polymer includes diene homopolymer, diene copolymer, diene prepolymer, and diene oligomer.

Unless otherwise specified, the term “copolymer” used herein refers to a product formed by two or more different monomers via polymerization, including random copolymers, alternating copolymers, graft copolymers, or block copolymers, but the present disclosure is not limited thereto. For instance, a styrene-butadiene copolymer is a product formed by only styrene and butadiene monomers via polymerization. For instance, the styrene-butadiene copolymer includes a styrene-butadiene random copolymer, a styrene-butadiene alternating copolymer, a styrene-butadiene graft copolymer, or a styrene-butadiene block copolymer, but the present disclosure is not limited thereto. For instance, the styrene-butadiene block copolymer includes a polymerized molecular structure of styrene-styrene-styrene-butadiene-butadiene-butadiene-butadiene, but the present disclosure is not limited thereto. For instance, the styrene-butadiene block copolymer includes a styrene-butadiene-styrene block copolymer, but the present disclosure is not limited thereto. For instance, the styrene-butadiene-styrene block copolymer includes a polymerized molecular structure of styrene-styrene-styrene-butadiene-butadiene-butadiene-butadiene-styrene-styrene-styrene, but the present disclosure is not limited thereto. Similarly, a hydrogenated styrene-butadiene copolymer includes a hydrogenated styrene-butadiene random copolymer, a hydrogenated styrene-butadiene alternating copolymer, a hydrogenated styrene-butadiene graft copolymer, or a hydrogenated styrene-butadiene block copolymer. For instance, the hydrogenated styrene-butadiene block copolymer includes a hydrogenated styrene-butadiene-styrene block copolymer, but the present disclosure is not limited thereto.

Unless otherwise specified, the term “resin” used herein should be interpreted as including a monomer, a polymer thereof, a combination of the monomer, a combination of the polymer, or a combination of the monomer and the polymer, but the present disclosure is not limited thereto. For instance, the term “maleimide resin” used herein should be interpreted as including a maleimide monomer, a maleimide polymer, a combination of the maleimide monomer, a combination of the maleimide polymer, or a combination of the maleimide monomer and the maleimide polymer.

The term “vinyl group-containing” used herein should be interpreted as including a vinyl group, a vinylbenzyl group, a vinylene group, an allyl group, or a (meth)acrylate group.

Unless otherwise specified, when a specific example of a compound is expressed as “(substituent)”, it should be interpreted as including both situations of containing and not containing this substituent. For instance, cyclohexane dimethanol di(meth)acrylate should be interpreted as including cyclohexane dimethanol diacrylate and cyclohexane dimethanol dimethacrylate, and (meth)acrylate should be interpreted as including acrylate and methacrylate.

Unless otherwise specified, the term “part(s) by weight” used herein represents weight part(s) in any weight unit, such as kilogram, gram, pound and so on, but the present disclosure is not limited thereto. For instance, 100 parts by weight of the vinyl group-containing resin may represent 100 kilograms of the vinyl group-containing resin or 100 pounds of the vinyl group-containing resin. In the case that the resin solution includes solvent and resin, the part(s) by weight of the (solid or liquid) resin generally refers to the weight unit of the (solid or liquid) resin and does not include the weight unit of the solvent in the solution, while the part(s) by weight of the solvent refers to the weight unit of the solvent.

One exemplary embodiment of the present disclosure provides a resin composition, including: a vinyl group-containing resin and a phosphorus-containing copolymer. The phosphorus-containing copolymer is polymerized from a monomer represented by Formula (1) and a monomer represented by Formula (2).

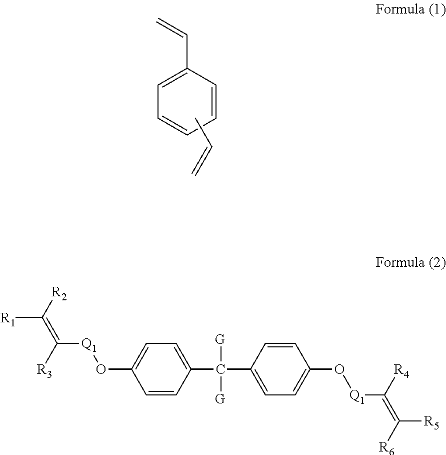

The monomer represented by Formula (1) may include 1,2-divinylbenzene, 1,3-divinylbenzene, and 1,4-divinylbenzene.

In Formula (2), each of R₁ to R₆ is independently selected from a hydrogen or a C1-C3 alkyl group.

In Formula (2), each G independently represents any one of a group represented by Formula (3) or a group represented by Formula (4) which is a monovalent phosphorus-containing functional group.

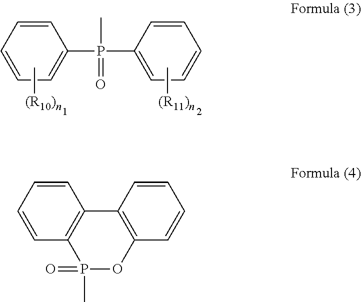

In Formula (3), each of R₇ to R₈ is independently a C1-C3 alkyl group, and each of n₁ to n₂ is independently an integer of 0 to 3.

In Formula (2), each Q1 independently represents any one of —CO— or *—CH₂—C₆H₄-which is a divalent functional group, and a symbol “*” represents a binding site which binds to an oxygen atom.

In one exemplary embodiment, a molar ratio of the monomer represented by Formula (1) to the monomer represented by Formula (2) may be 1:7 to 3:7.

In one exemplary embodiment, a weight average molecular weight of the phosphorus-containing copolymer may be 2,000 to 4,000.

In one exemplary embodiment, the resin composition may include 100 parts by weight of the vinyl group-containing resin and 25 to 50 parts by weight of the phosphorus-containing copolymer. For instance, the resin composition in the present disclosure may include 100 kilograms of the vinyl group-containing resin and 25 to 50 kilograms of the phosphorus-containing copolymer.

In one exemplary embodiment, the vinyl group-containing resin may include a vinyl group-containing polyphenylene ether resin, a maleimide resin, an ethylene propylene diene rubber, a compound represented by Formula (5), a styrene-butadiene copolymer, a polybutadiene, a diene group-containing fluorene compound, a hydrogenated polybutadiene resin terminated with divinylbenzene, or a combination thereof.

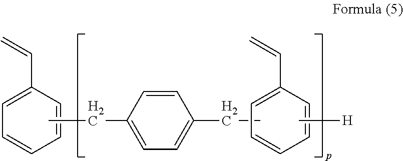

In Formula (5), p may be an integer of 1 to 20.

In one exemplary embodiment, the vinyl group-containing polyphenylene ether resin may include various polyphenylene ether resins whose terminal is modified with a vinyl group or an allyl group. In addition, the vinyl group-containing polyphenylene ether resin may also be polyphenylene ether resin whose terminal is modified with a (meth)acrylate group.

In one exemplary embodiment, the vinyl group-containing polyphenylene ether resin refers to polyphenylene ether resin containing a vinyl group, and the examples thereof may include polyphenylene ether resin containing a vinyl group, an allyl group, a vinylbenzyl group, or a (meth)acrylate group, but the present disclosure is not limited thereto. For instance, the vinyl group-containing polyphenylene ether resin may include a vinylbenzyl group-containing biphenyl polyphenylene ether resin, a (meth)acrylate polyphenylene ether resin (i.e., (meth)acryloyl group-containing polyphenylene ether resin), an allyl group-containing polyphenylene ether resin, a vinylbenzyl group-modified bisphenol A polyphenylene ether resin, a vinyl group-containing chain-extended polyphenylene ether resin or a combination thereof. For instance, the vinyl group-containing polyphenylene ether resin may be a vinylbenzyl group-containing biphenyl polyphenylene ether resin with a number average molecular weight of about 1200 (such as OPE-2st 1200, available from Mitsubishi Gas Chemical Co., Inc.), a vinylbenzyl group-containing biphenyl polyphenylene ether resin with a number average molecular weight of about 2200 (such as OPE-2st 2200, available from Mitsubishi Gas Chemical Co., Inc.), a methacrylate polyphenylene ether resin with a number average molecular weight of about 1900 to 2300 (such as SA9000, available from Sabic company), a vinylbenzyl group-modified bisphenol A polyphenylene ether resin with a number average molecular weight of about 2400 to 2800, a vinyl group-containing chain-extended polyphenylene ether resin with a number average molecular weight of about 2200 to 3000 or a combination thereof. Among them, the vinyl group-containing chain-extended polyphenylene ether resin may include various polyphenylene ether resins disclosed in the US Patent Application Publication No. 2016/0185904 A1, all of which are incorporated herein by reference in their entirety.

In one exemplary embodiment, the maleimide resin may include monomers having one or more maleimide groups in the molecule or a combination thereof. Unless otherwise specified, the maleimide resin applied in the present disclosure is not particularly limited, and may be one or more maleimide resins suitable for manufacturing prepregs, resin films, laminates, or printed circuit boards. For instance, the maleimide resin may include 4,4′-diphenylmethane bismalcimide, oligomer of phenylmethane maleimide (or polyphenylmethane maleimide), bisphenol A diphenyl ether bismaleimide, 3,3′-dimethyl-5,5′-diethyl-4,4′-diphenylmethane bismaleimide (or bis(3-ethyl-5-methyl-4-maleimidephenyl) methane), 3,3′-dimethyl-5,5′-dipropyl-4,4′-diphenylmethane bismalcimide, biphenyl maleimide, m-phenylene bismaleimide, 4-methyl-1,3-phenylene bismaleimide, 1,6-bismaleimide-(2,2,4-trimethyl) hexane, N-2,3-xylylmaleimide, N-2,6-xylylmaleimide, N-phenylmaleimide, diethyl bismaleimidotoluene, vinyl benzyl maleimide (VBM), aliphatic long chain structure-containing maleimide resin, or a combination thereof. Unless otherwise specified, the maleimide resin should be interpreted as including modifications thereof.

For instance, the maleimide resin may be maleimide resin product BMI-1000, BMI-1000H, BMI-1100, BMI-1100H, BMI-2000, BMI-2300, BMI-3000, BMI-3000H, BMI-4000, BMI-5000, BMI-5100, BMI-TMH, BMI-7000 or BMI-7000H available from Daiwakasei Industry Co., Ltd.; maleimide resin product BMI-70 or BMI-80 available from K.I Chemical Co., Ltd.; maleimide resin product MIR-3000 or MIR-5000 available from Nippon Kayaku; or maleimide resin product DE-TDAB available from Evonik Industries.

For instance, the aliphatic long chain structure-containing maleimide resin may be maleimide resin product BMI-689, BMI-1400, BMI-1500, BMI-1700, BMI-2500, BMI-3000, BMI-5000 or BMI-6000 available from Designer Molecules Inc.

In one exemplary embodiment, the resin composition may further include a compound represented by Formula (6).

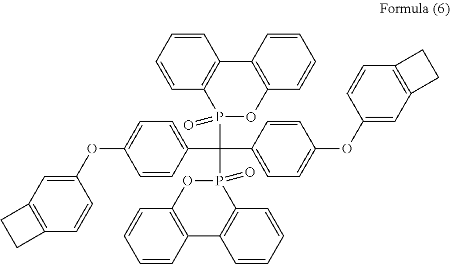 [SMILES: O=P1(C(c2ccc(Oc3ccc4c(c3)CC4)cc2)(c2ccc(Oc3ccc4c(c3)CC4)cc2)P2(=O)Oc3ccccc3-c3ccccc32)Oc2ccccc2-c2ccccc21]

In one exemplary embodiment, the resin composition may include 100 parts by weight of the vinyl group-containing resin and 15 to 25 parts by weight of the compound represented by Formula (6). For instance, the resin composition in the present disclosure may include 100 kilograms of the vinyl group-containing resin and 15 to 25 kilograms of the compound represented by Formula (6).

In one exemplary embodiment, the resin composition may further include an inorganic filler, a curing accelerator, a flame retardant, a polymerization inhibitor, a solvent, a silane coupling agent, a coloring agent, a toughening agent, or a combination thereof.

In one exemplary embodiment, the inorganic filler may be silica. In one exemplary embodiment, the amount of the inorganic filler may be 60 parts by weight to 100 parts by weight, with respect to 100 parts by weight of the vinyl group-containing resin. In one exemplary embodiment, the inorganic filler may be spherical silica. In one exemplary embodiment, the spherical silica may include various spherical silicas known in this field. The spherical silica suitable for the present disclosure is not particularly limited and may be any one or more of commercial products.

In one exemplary embodiment, the inorganic filler may be an inorganic filler other than the spherical silica, and the amount thereof may be adjusted as needed. In one exemplary embodiment, the inorganic filler other than the spherical silica may include non-spherical silica (i.e., irregular silica known in the field, wherein irregular means not spherical), aluminum oxide, aluminum hydroxide, magnesium oxide, magnesium hydroxide, calcium carbonate, aluminum nitride, boron nitride, aluminum silicon carbide, silicon carbide, titanium dioxide, barium titanate, lead titanate, strontium titanate, calcium titanate, magnesium titanate, barium zirconate, lead zirconate, magnesium zirconate, lead zirconate titanate, zinc molybdate, calcium molybdate, magnesium molybdate, ammonium molybdate, zinc molybdate-modified talc, zinc oxide, zirconium oxide, mica, bochmite (AlOOH), calcined talc, talc, silicon nitride, or calcined kaolin, but the present disclosure is not limited thereto. In addition, except for the non-spherical silica, other inorganic fillers may be spherical, fibrous, plate, particulate, flake or whisker.

In one exemplary embodiment, the silane coupling agent may include silane (such as siloxane, but the present disclosure is not limited thereto), and based on the functional group, the silane may be divided into amino silane, epoxide silane, vinyl silane, ester silane, hydroxyl silane, isocyanate silane, methacryloyloxyl silane and acryloyloxyl silane.

In one exemplary embodiment, the polymerization inhibitor may include various molecule type polymerization inhibitors or stable free radical type polymerization inhibitors known in this field. The molecule type polymerization inhibitor may include phenols, quinones, arylamines, arene nitro compounds, sulfur-containing compounds or chlorides of metal with variable valency, but the present disclosure is not limited thereto. For instance, the molecule type polymerization inhibitor may include phenol, hydroquinone, 4-tert-butylcatechol, benzoquinone, chloroquinone, 1,4-naphthoquinone, trimethylquinone, aniline, nitrobenzene, Na₂S, FeCl₃ or CuCl₂, but the present disclosure is not limited thereto. For instance, the stable free radical type polymerization inhibitor may include 1,1-diphenyl-2-picrylhydrazyl radical (DPPH), triphenylmethyl radical, 2,2,6,6-tetramethylpiperidine-1-oxide or derivatives of 2,2,6,6-tetramethylpiperidine-1-oxide, but the present disclosure is not limited thereto.

In one exemplary embodiment, the flame retardant may include a phosphorus-containing flame retardant, but the present disclosure is not limited thereto. For instance, the phosphorus-containing flame retardant may include ammonium polyphosphate, hydroquinone bis(diphenyl phosphate), bisphenol A bis(diphenylphosphate), tri(2-carboxyethyl) phosphine (TCEP), tris(chloroisopropyl) phosphate, trimethyl phosphate (TMP), dimethyl methyl phosphonate (DMMP), resorcinol bis(dixylenyl phosphate), resorcinol bis(di-2,6-dimethylphenyl phosphate) (such as commercial product PX-200), hydroquinone bis(di-2,6-dimethylphenyl phosphate) (such as commercial product PX-201), 4,4′-biphenol bis(di-2,6-dimethylphenyl phosphate) (such as commercial product PX-202), phosphazene (such as commercial product SPB-100, SPH-100 or SPV-100), melamine polyphosphate, 9,10-dihydro-9-oxa-10-phosphaphenanthrene-10-oxide (DOPO) and its derivatives (such as di-DOPO compounds) or resins (such as DOPO-HQ, DOPO-NQ, DOPO-PN or DOPO-BPN), DOPO-bonding epoxy resin, diphenylphosphine oxide (DPPO) and its derivatives (such as di-DPPO compounds) or resins, melamine cyanurate, tri-hydroxyethyl isocyanurate or aluminium phosphinate (such as commercial product OP-930 or OP-935). Among them, DOPO-PN is DOPO-containing phenol novolac resin, and DOPO-BPN may be bisphenol novolac resin such as DOPO-BPAN (DOPO-bisphenol A novolac), DOPO-BPFN (DOPO-bisphenol F novolac) or DOPO-BPSN (DOPO-bisphenol S novolac), but the present disclosure is not limited thereto.

In one exemplary embodiment, the curing accelerator may include an initiator, but the present disclosure is not limited thereto. For instance, the initiator may include bis(tert-butylperoxyisopropyl)benzene, 2,5-dimethyl-2,5-di(tert-butylperoxy)-3-hexyne, dibenzoyl peroxide, 2,3-dimethyl-2,3-diphenylbutane, dicumyl peroxide, tert-butyl peroxybenzoate, tert-butyl peroxyisopropyl monocarbonate, azobisisobutylonitrile or 2,2′-azobis(2,4,4-trimethylpentane), but the present disclosure is not limited thereto. In one exemplary embodiment, the amount of the initiator may be 0.1 parts by weight to 0.2 parts by weight, with respect to 100 parts by weight of the vinyl group-containing resin.

In one exemplary embodiment, the coloring agent may include dye or pigment, but the present disclosure is not limited thereto.

In one exemplary embodiment, the main purpose of adding the toughening agent is to improve the toughness of the resin composition, and the toughening agent may include rubbers such as carboxyl-terminated butadiene acrylonitrile rubber (CTBN), but the present disclosure is not limited thereto.

In one exemplary embodiment, the main purpose of adding the solvent is to dissolve the components in the resin composition, to modify the solid content of the resin composition, and to adjust the viscosity of the resin composition. For instance, the solvent may include methanol, ethanol, ethylene glycol monomethyl ether, acetone, butanone (i.e., methyl ethyl ketone), methyl isobutyl ketone, cyclohexanone, toluene, xylene, methoxyethyl acetate, ethoxyethyl acetate, propoxyethyl acetate, ethyl acetate, propylene glycol methyl ether, dimethyl formamide, dimethyl acetamide, N-methylpyrrolidone or a mixed solvent thereof, but the present disclosure is not limited thereto. The amount of the solvent is not particularly limited and may be adjusted depending on the desired viscosity of the resin composition. In the case of adding the solvent to the resin composition, the solvent is evaporated and removed during heating the resin composition at high temperature to form a semi-cured state, and thus no solvent or only a trace amount of the solvent is present in the article. Therefore, the presence or absence of the solvent in the resin composition does not affect the properties of the article.

The resin composition of one exemplary embodiment of the present disclosure may be made into various articles including a prepreg, a resin film, a laminate, or a printed circuit board by various processing ways, but the present disclosure is not limited thereto.

In one exemplary embodiment, the resin composition of the present disclosure may be made into a prepreg, which includes a reinforcement material and a layered structure disposed thereon. The layered structure is formed by heating the resin composition at a high temperature to a semi-cured state (B-stage). The baking temperature for making the prepreg may be between 100° C. and 140° C. The reinforcement material may be any one of fiber material, woven fabric and non-woven fabric. The woven fabric may include fiberglass fabrics. The types of the fiberglass fabrics are not particularly limited and may be various fiberglass fabrics used for printed circuit boards, such as E-glass fabric, D-glass fabric, S-glass fabric, T-glass fabric, L-glass fabric or Q-glass fabric; and the type of the fiberglass may include yarns and rovings, in spread form or standard form. The non-woven fabric may include liquid crystal resin non-woven fabric, such as polyester non-woven fabric, polyurethane non-woven fabric and so on, but the present disclosure is not limited thereto. The woven fabric may also include liquid crystal resin woven fabric, such as polyester woven fabric, polyurethane woven fabric and so on, but the present disclosure is not limited thereto. The reinforcement material may increase the mechanical strength of the prepreg.

In one exemplary embodiment, the resin composition of the present disclosure may be made into a resin film, which is prepared by heating and baking to semi-cure the resin composition. The resin composition may be selectively coated on a polyethylene terephthalate film (PET film), a polyimide film (PI film), a copper foil or a resin-coated copper, followed by heating and baking to a semi-cured state so as to make the resin composition into the resin film.

In one exemplary embodiment, the resin composition of the present disclosure may be made into a laminate, which includes at least two metal foils and at least one insulation layer disposed between the two metal foils. The insulation layer may be made by curing the resin composition at high temperature and high pressure to C-stage, wherein a suitable curing temperature may be between 180° C. and 250° C., preferably between 200° C. and 220° C., and a curing time may be 80 to 150 minutes, preferably 90 to 120 minutes. The insulation layer may be formed by curing the prepreg or the resin film to C-stage. The material of the metal foil may be copper, aluminum, nickel, platinum, silver, gold, or alloy thereof. For instance, the metal foil may be a copper foil. In one exemplary embodiment, the laminate is a copper-clad laminate (CCL).

In one exemplary embodiment, the laminate may be further processed by circuit formation processes to be made into a circuit board, such as a printed circuit board.

In one exemplary embodiment, the article made from the resin composition of the present disclosure may have at least one of the following properties:
a dissipation factor at 10 Hz as measured by reference to JIS C2565 of less than or equal to 0.0030, such as between 0.0020 and 0.0028;
a copper foil peeling strength as measured by reference to IPC-TM-650 2.4.8 of greater than or equal to 3.00 lb/in, such as between 3.14 lb/in and 3.38 lb/in;
a flame retardancy as measured by reference to UL94 rating of V-0; and
an X-axis coefficient of thermal expansion as measured by reference to IPC-TM-650 2.4.24.5 of less than or equal to 14.00 ppm/° C., such as between 12.81 ppm/° C. and 13.91 ppm/° C.

The chemical materials used in Synthesis Examples of the copolymer, Examples of the resin composition, and Comparative Examples of the resin composition are described as follows:

Copolymer CP1 to Copolymer CP6: prepared by Synthesis Example 1 to Synthesis Example 6.

OPE-2st 2200: polyphenylene ether resin with a vinylbenzyl group at its terminal, available from Mitsubishi Gas.

SA9000: methacrylate-containing polyphenylene ether resin, available from Sabic company.

MIR-5000: maleimide resin represented by Formula (7), where 1≤m≤5, available from Nippon Kayaku.

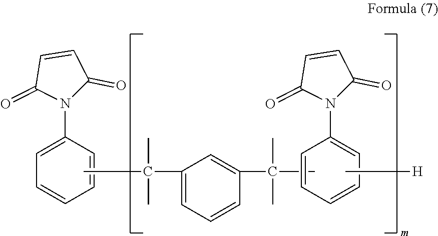

Trilene® 67: ethylene propylene diene rubber, available from Lion Elastomers.

Compound of Formula (5): the compound represented by Formula (5), prepared by Synthesis Example 7.

Ricon 100: styrene-butadiene copolymer, available from Cray Valley.

B-1000: polybutadiene resin, available from Nippon Soda.

CHR-2st: diene group-containing fluorene compound, available from Shandong Xingshun New Material Co., Ltd.

MD3501: hydrogenated polybutadiene resin terminated with divinylbenzene, available from Kraton Corporation. 1,4-divinylbenzene: commercially available.

Compound of Formula (2.1): the compound represented by Formula (2.1), available from Cheng Ci corporation.

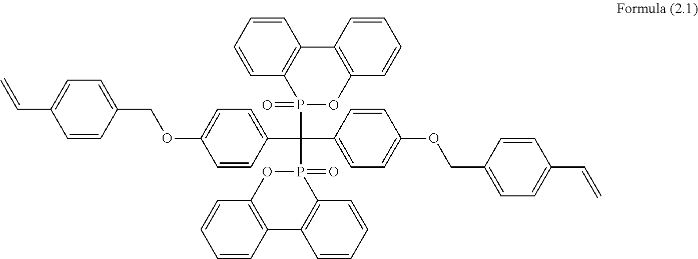 [SMILES: C=Cc1ccc(COc2ccc(C(c3ccc(OCc4ccc(C=C)cc4)cc3)(P3(=O)Oc4ccccc4-c4ccccc43)P3(=O)Oc4ccccc4-c4ccccc43)cc2)cc1]

Compound of Formula (6): the compound represented by Formula (6), available from Cheng Ci corporation.

SC2050: silica, available from Admatechs.

2,2′-azobis(2,4,4-trimethylpentane): commercially available.

MEK: butanone, commercially available.

### Synthesis Example 1

0.7 moles of a compound represented by Formula (2.1) (available from Cheng Ci corporation) and DMAc/MEK (with a weight ratio of 1:2) are added to a reaction device, and stirred and dissolved at 120° C. Then, they are cooled down to 60° C. 0.3 moles of 1,4-divinylbenzene and azobisisobutyronitrile (AIBN) which weighs 0.5 wt % of the weight of the aforementioned raw materials (without solvent) are further added thereto to react for 4 hours at 60° C. so as to obtain copolymer CP1 of the present disclosure with a solid content of 50% to 60%. The weight average molecular weight of the copolymer CP1 is about 3,600, which is measured by Gel Permeation Chromatograph (GPC).

### Synthesis Example 2

0.7 moles of a compound represented by Formula (2.2) and DMAc/MEK (with a weight ratio of 1:2) are added to a reaction device, and stirred and dissolved at 120° C. Then, they are cooled down to 60° C. 0.3 moles of 1,4-divinylbenzene and azobisisobutyronitrile (AIBN) which weighs 0.5 wt % of the weight of the aforementioned raw materials (without solvent) are further added thereto to react for 4 hours at 60° C. so as to obtain copolymer CP2 of the present disclosure with a solid content of 50% to 60%. The weight average molecular weight of the copolymer CP2 is about 3,800, which is measured by Gel Permeation Chromatograph (GPC).

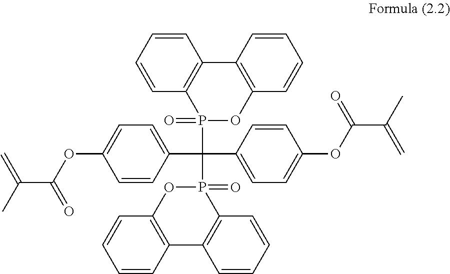 [SMILES: C=C(C)C(=O)Oc1ccc(C(c2ccc(OC(=O)C(=C)C)cc2)(P2(=O)Oc3ccccc3-c3ccccc32)P2(=O)Oc3ccccc3-c3ccccc32)cc1]

### Synthesis Example 3

0.7 moles of a compound represented by Formula (2.3) and DMAc/MEK (with a weight ratio of 1:2) are added to a reaction device, and stirred and dissolved at 120° C. Then, they are cooled down to 60° C. 0.3 moles of 1,4-divinylbenzene and azobisisobutyronitrile (AIBN) which weighs 0.5 wt % of the weight of the aforementioned raw materials (without solvent) are further added thereto to react for 4 hours at 60° C. so as to obtain copolymer CP3 of the present disclosure with a solid content of 50% to 60%. The weight average molecular weight of the copolymer CP3 is about 3,800, which is measured by Gel Permeation Chromatograph (GPC).

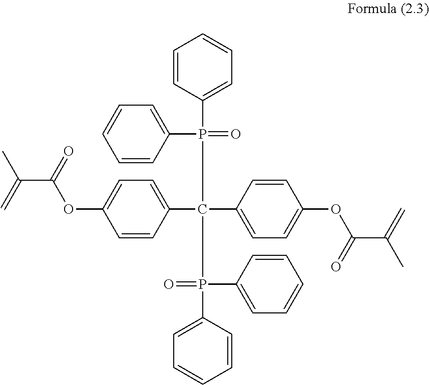 [SMILES: C=C(C)C(=O)Oc1ccc(C(c2ccc(OC(=O)C(=C)C)cc2)(P(=O)(c2ccccc2)c2ccccc2)P(=O)(c2ccccc2)c2ccccc2)cc1]

### Synthesis Example 4

0.5 moles of 1,4-divinylbenzene, benzoyl peroxide (BPO) which weighs 0.5 wt % of the weight of the aforementioned raw materials (without solvent), and appropriate amount of toluene are added to a reaction device to react for 4 hours at 90° C. so as to obtain copolymer CP4 of the present disclosure. The weight average molecular weight of the copolymer CP4 is about 3,900, which is measured by Gel Permeation Chromatograph (GPC).

### Synthesis Example 5

0.7 moles of SPV-100 (commercially available) and DMAc/MEK (with a weight ratio of 1:2) are added to a reaction device, and stirred and dissolved at 120° C. Then, they are cooled down to 60° C. 0.3 moles of 1,4-divinylbenzene and azobisisobutyronitrile (AIBN) which weighs 0.5 wt % of the weight of the aforementioned raw materials (without solvent) are further added thereto to react for 4 hours at 60° C. so as to obtain copolymer CP5 of the present disclosure with a solid content of 50% to 60%. The weight average molecular weight of the copolymer CP5 is about 3,700, which is measured by Gel Permeation Chromatograph (GPC).

### Synthesis Example 6

0.7 moles of styrene and DMAc/MEK (with a weight ratio of 1:2) are added to a reaction device, and stirred and dissolved at 120° C. Then, they are cooled down to 60° C. 0.3 moles of 1,4-divinylbenzene and azobisisobutyronitrile (AIBN) which weighs 0.5 wt % of the weight of the aforementioned raw materials (without solvent) are further added thereto to react for 4 hours at 60° C. so as to obtain copolymer CP6 of the present disclosure with a solid content of 50% to 60%. The weight average molecular weight of the copolymer CP6 is about 3,500, which is measured by Gel Permeation Chromatograph (GPC).

### Synthesis Example 7

296 parts by weight of (2-bromoethyl)benzene (available from Tokyo Chemical Industry Co., Ltd.), 70 parts by weight of α,α′-dichloro-p-xylene (available from Tokyo Chemical Industry Co., Ltd.) and 18.4 parts by weight of methanesulfonic acid (available from Tokyo Chemical Industry Co., Ltd.) are reacted at 130° C. for 8 hours, then cooled down to room temperature, neutralized by sodium hydroxide, and then extracted with 1200 parts by weight of toluene. The organic layer is washed with water. The solvent and the excessive (2-bromoethyl)benzene are removed by distillation under heating and reduced pressure to obtain an intermediate. In this Synthesis Example, the reaction temperature may be 40° C. to 180° C., the reaction time may be 0.5 to 20 hours, and a molar ratio of (2-bromoethyl)benzene to α,α′-dichloro-p-xylene may be 4:1. Further, methanesulfonic acid serves as an acidic catalyst, but the present disclosure is not limited thereto. For instance, the acidic catalyst may be other acidic catalyst such as hydrochloric acid or phosphoric acid.

22 parts by weight of the intermediate, 50 parts by weight of toluene (other aromatic solvents such as xylene may also be used), 150 parts by weight of dimethyl sulfoxide (other aprotic polar solvents such as dimethyl sulfone may also be used), 15 parts by weight of water and 5.4 parts by weight of sodium hydroxide (other basic catalysts such as potassium hydroxide and potassium carbonate may also be used) are reacted at 40° C. for 5 hours, then cooled down to room temperature, and 100 parts by weight of toluene is added thereto. The organic layer is washed with water. The solvent is removed by distillation under heating and reduced pressure to obtain a compound represented by Formula (5).

The resin compositions of Examples and Comparative Examples of the present disclosure are prepared according to the amount of the chemical materials listed in Tables 1 to 3 and further made into various samples (test samples). The samples are prepared according to the following methods, and the property tests thereof are performed based on the specific test conditions.

### 1. Prepreg 1 (PP 1)

The resin compositions (in parts by weight) from each Examples and each Comparative Examples are used, and the components thereof are separately added to a stirring tank and well-mixed to form a varnish. The varnish is loaded into an impregnation tank, and a fiberglass fabric (e.g., 1078 L-glass fiber fabric, available from Asahi) is immersed into the impregnation tank to adhere the resin composition onto the fiberglass fabric, followed by heating at 100° C. to 140° C. to a semi-cured state (B stage), thereby obtaining Prepreg 1 with a resin content of 70%.

### 2. Prepreg 2 (PP 2)

The resin compositions from each Examples and each Comparative Examples are used, and the components thereof are separately added to a stirring tank and well-mixed to form a varnish. The varnish is loaded into an impregnation tank, and a fiberglass fabric (e.g., 2116 L-glass fiber fabric, available from Asahi) is immersed into the impregnation tank to adhere the resin composition onto the fiberglass fabric, followed by heating at 100° C. to 140° C. to a semi-cured state (B stage), thereby obtaining Prepreg 2 with a resin content of 70%.

### 3. Copper-Clad Laminate 1 (Formed by Laminating Two Prepregs 1)

Two hyper very low profile (HVLP) copper foils with a thickness of 1 ounce and two Prepregs obtained from 1078 L-glass fiber fabrics impregnated with samples of each of Examples and Comparative Examples and each having a resin content of about 70% are prepared. They are stacked in an order of one copper foil, two Prepregs and one copper foil, followed by lamination under vacuum at 250 psi to 600 psi and 200° C. to 220° C. for 90 minutes to 120 minutes to form Copper-clad laminate 1. The two Prepregs are cured and formed into an insulation layer between the two copper foils, and the insulation layer has a resin content of about 70%.

### 4. Copper-Free Laminate 1 (Formed by Laminating Two Prepregs 1)

Copper-clad laminate 1 formed by laminating two Prepregs 1 is etched to remove the two copper foils, thereby obtaining Copper-free laminate 1 (formed by laminating two Prepregs 1).

### 5. Copper-Clad Laminate 2 (Formed by Laminating Two Prepregs 2)

The preparation method of Copper-clad laminate 2 is basically the same as that of Copper-clad laminate 1, and the difference is that such preparation method uses Prepreg 2.

### 6. Copper-Free Laminate 2 (Formed by Laminating Two Prepregs 2)

Copper-clad laminate 2 formed by laminating two Prepregs 2 is etched to remove the two copper foils, thereby obtaining Copper-free laminate 2 (formed by laminating two Prepregs 2).

### 7. Copper-Clad Laminate 3 (Formed by Laminating Six Prepregs 1)

The preparation method of Copper-clad laminate 3 is basically the same as that of Copper-clad laminate 1, and the difference is that the insulation layer is composed of six Prepregs 1.

### 8. Copper-Clad Laminate 4 (Formed by Laminating Eight Prepregs 1)

The preparation method of Copper-clad laminate 4 is basically the same as that of Copper-clad laminate 1, and the difference is that the insulation layer is composed of eight Prepregs 1.

### 9. Copper-Free Laminate 3 (Formed by Laminating Eight Prepregs 1)

Copper-clad laminate 4 formed by laminating eight Prepregs 1 is etched to remove the two copper foils, thereby obtaining Copper-free laminate 3 (formed by laminating eight Prepregs 1).

For above samples, the test method and the property analysis are described below.

### Dissipation Factor (Df)

In the measurement of the dissipation factor, the above Copper-free laminates 1 (formed by laminating two Prepregs 1, with a resin content of about 70%) is used as a sample. Each sample is measured for the dissipation factor at 10 GHz at room temperature (about 25° C.) by reference to JIS C2565 using a microwave dielectrometer (available from AET Corp.). At a measurement frequency of 10 GHz, for Df value between 0.0010 and 0.0045, a difference in Df values of less than 0.00030 represents no significant difference in dissipation factors of different laminates (i.e., no significant technical difficulty is present), while a difference in Df values of greater than or equal to 0.00030 represents a significant difference in dissipation factors of different laminates (i.e., significant technical difficulty is present).

### Copper Foil Peeling Strength (1 Ounce) (1 Oz Peeling Strength, 1 Oz P/S)

One Copper-clad laminate 3 (formed by laminating six Prepregs 1) is prepared and cut into a rectangular sample with a width of 24 mm and a length of 80 mm, and the sample is etched to remove the surface copper foil and leave a strip copper foil with a width of 3.18 mm and a length of greater than 60 mm. The sample is measured for one-ounce copper foil peeling strength (1 oz P/S) in lb/in at room temperature (about 25° C.) by reference to IPC-TM-650 2.4.8 using a universal tensile strength tester. In this field, the higher copper foil peeling strength is better.

### Flame Resistance

One Copper-free laminate 3 (formed by laminating eight Prepregs 1) is prepared and used as a sample. The flame retardancy test is performed in accordance with the UL 94 rating, and the results are represented by V-0, V-1, or V-2, wherein V-O indicates a superior flame retardancy to V-1, V-1 indicates a superior flame retardancy to V-2, and burn out indicates the worst case.

### X-Axis Coefficient of Thermal Expansion (X-CTE)

One Copper-free laminate 2 (formed by laminating two Prepregs 2) is prepared and used as a sample for thermal mechanical analysis (TMA). Copper-free laminate 2 is cut into a sample with a length of 24 mm and a width of 3 mm. The sample is heated at a rate of 10° C. per minute from 35° C. to 350° C., and each sample is measured for X-axis coefficient of thermal expansion (in ppm/° C.) in a temperature range (α1) of 40° C. to 125° C. by reference to IPC-TM-650 2.4.24.5. The X-axis coefficient of thermal expansion herein refers to the coefficient of thermal expansion in X-axis direction of the sample. The lower X-axis coefficient of thermal expansion means a better dimensional change property. A difference in X-axis coefficient of thermal expansions of greater than or equal to 1.0 ppm/° C. represents a significant difference in X-axis coefficient of thermal expansions of different laminates (i.e., significant technical difficulty is present).

TABLE 1
The components of the resin compositions (in parts by weight) and the property
test results of Examples E1 to E7. (PA represents proper amount.)

| Component | Name | E1 | E2 | E3 | E4 | E5 | E6 | E7 |
|---|---|---|---|---|---|---|---|---|
| Copolymer | CP1 | 35 | 35 | 35 | — | — | 25 | 50 |
| | CP2 | — | — | — | 35 | — | — | — |
| | CP3 | — | — | — | — | 35 | — | — |
| | CP4 | — | — | — | — | — | — | — |
| | CP5 | — | — | — | — | — | — | — |
| | CP6 | — | — | — | — | — | — | — |
| Vinyl | OPE-2st 2200 | — | 10 | — | 5 | 5 | — | — |
| group- | SA9000 | 100 | 10 | 50 | 50 | 5 | 100 | 100 |
| containing | MIR-5000 | — | 10 | — | 10 | — | — | — |
| resin | Trilene ® 67 | — | — | 10 | 10 | — | — | — |
| | Compound of | — | — | 20 | — | 40 | — | — |
| | Formula (5) | | | | | | | |
| | Ricon 100 | — | — | 5 | — | 30 | — | — |
| | B-1000 | — | 5 | — | — | 20 | — | — |
| | CHR-2st | — | — | 15 | 15 | — | — | — |
| | MD3501 | — | 65 | — | 10 | — | — | |
| Additive | 1,4- | — | — | — | — | — | — | — |
| | divinylbenzene | | | | | | | |
| | Compound of | — | — | — | — | — | — | — |
| | Formula (2.1) | | | | | | | |
| | Compound of | — | — | — | — | — | — | — |
| | Formula (6) | | | | | | | |
| Filler | SC2050 | 80 | 80 | 80 | 80 | 80 | 80 | 80 |
| Initiator | 2,2′-azobis(2,4,4- | 0.15 | 0.15 | 0.15 | 0.15 | 0.15 | 0.15 | 0.15 |
| | trimethylpentane) | | | | | | | |
| Solvent | MEK | PA | PA | PA | PA | PA | PA | PA |
| Property | Unit | E1 | E2 | E3 | E4 | E5 | E6 | E7 |
| Df@10 GHz | — | 0.0026 | 0.0025 | 0.0026 | 0.0024 | 0.0023 | 0.0023 | 0.0028 |
| P/S | lb/in | 3.15 | 3.21 | 3.17 | 3.14 | 3.24 | 3.19 | 3.15 |
| UL-94 | — | V-0 | V-0 | V-0 | V-0 | V-0 | V-0 | V-0 |
| X-CTE | ppm/° C. | 13.25 | 13.13 | 13.75 | 13.86 | 13.05 | 13.61 | 13.39 |

TABLE 2
The components of the resin compositions (in parts by weight) and the property
test results of Examples E8 to E13. (PA represents proper amount.)

| Component | Name | E8 | E9 | E10 | E11 | E12 | E13 |
|---|---|---|---|---|---|---|---|
| Copolymer | CP1 | 35 | 35 | 35 | 35 | 35 | 35 |
| | CP2 | — | — | — | — | — | — |
| | CP3 | — | — | — | — | — | — |
| | CP4 | — | — | — | — | — | — |
| | CP5 | — | — | — | — | — | — |
| | CP6 | — | — | — | — | — | — |
| Vinyl | OPE-2st 2200 | — | — | — | — | — | — |
| group- | SA9000 | 100 | 100 | 100 | 100 | 100 | 100 |
| containing | MIR-5000 | — | — | — | — | — | — |
| resin | Trilene ® 67 | — | — | — | — | — | — |
| | Compound of | — | — | — | — | — | — |
| | Formula (5) | | | | | | |
| | Ricon 100 | — | — | — | — | — | — |
| | B-1000 | — | — | — | — | — | — |
| | CHR-2st | — | — | — | — | — | — |
| | MD3501 | — | — | — | — | — | — |
| Additive | 1,4-divinylbenzene | — | — | — | — | — | — |
| | Compound of | — | — | — | — | — | — |
| | Formula (2.1) | | | | | | |
| | Compound of | — | — | — | — | 15 | 25 |
| | Formula (6) | | | | | | |
| Filler | SC2050 | 60 | 100 | 80 | 80 | 80 | 80 |
| Initiator | 2,2′-azobis(2,4,4- | 0.15 | 0.15 | 0.10 | 0.20 | 0.20 | 0.20 |
| | trimethylpentane) | | | | | | |
| Solvent | MEK | PA | PA | PA | PA | PA | PA |
| Property | Unit | E8 | E9 | E10 | E11 | E12 | E13 |
| Df@10 GHz | — | 0.0026 | 0.0025 | 0.0024 | 0.0025 | 0.0021 | 0.0020 |
| P/S | lb/in | 3.19 | 3.14 | 3.15 | 3.14 | 3.34 | 3.38 |
| UL-94 | — | V-0 | V-0 | V-0 | V-0 | V-0 | V-0 |
| X-CTE | ppm/° C. | 13.91 | 13.09 | 13.64 | 13.87 | 12.97 | 12.81 |

TABLE 3
The components of the resin compositions (in parts by weight) and the property
test results of Comparative Examples C1 to C6. (PA represents proper amount.)

| Component | Name | C1 | C2 | C3 | C4 | C5 | C6 |
|---|---|---|---|---|---|---|---|
| Copolymer | CP1 | — | — | — | — | 15 | 70 |
| | CP2 | — | — | — | — | — | — |
| | CP3 | — | — | — | — | — | — |
| | CP4 | 35 | — | — | — | — | — |
| | CP5 | — | 35 | — | — | — | — |
| | CP6 | — | — | 35 | — | — | — |
| Vinyl | OPE-2st 2200 | — | — | — | — | — | — |
| group- | SA9000 | 100 | 100 | 100 | 100 | 100 | 100 |
| containing | MIR-5000 | — | — | — | — | — | — |
| resin | Trilene ® 67 | — | — | — | — | — | — |
| | Compound of | — | — | — | — | — | — |
| | Formula (5) | | | | | | |
| | Ricon 100 | — | — | — | — | — | — |
| | B-1000 | — | — | — | — | — | — |
| | CHR-2st | — | — | — | — | — | — |
| | MD3501 | — | — | — | — | — | — |
| Additive | 1,4-divinylbenzene | — | — | — | 2.1 | — | — |
| | Compound of | — | — | — | 32.9 | — | — |
| | Formula (2.1) | | | | | | |
| | Compound of | — | — | — | — | — | — |
| | Formula (6) | | | | | | |
| Filler | SC2050 | 80 | 80 | 80 | 80 | 80 | 80 |
| Initiator | 2,2′-azobis(2,4,4- | 0.15 | 0.15 | 0.15 | 0.15 | 0.15 | 0.15 |
| | trimethylpentane) | | | | | | |
| Solvent | MEK | PA | PA | PA | PA | PA | PA |
| Property | Unit | C1 | C2 | C3 | C4 | C5 | C6 |
| Df@10 GHz | — | 0.0028 | 0.0037 | 0.0039 | 0.0036 | 0.0037 | 0.0044 |
| P/S | 1b/in | 2.91 | 2.94 | 2.98 | 2.57 | 3.13 | 2.67 |
| UL-94 | — | Burn | V-0 | V-0 | Burn | V-1 | V-0 |
| | | out | | | out | | |
| X-CTE | ppm/° C. | 15.37 | 15.33 | 15.42 | 15.31 | 16.07 | 15.87 |

The following observations can be made from Table 1 to Table 3.

All of the samples of Examples E1 to E13 which use the resin compositions of the present disclosure can achieve the following properties: a dissipation factor of less than or equal to 0.0030, a copper foil peeling strength of greater than or equal to 3.00 lb/in, a flame retardancy of V-0, and an X-axis coefficient of thermal expansion of less than or equal to 14.00 ppm/° C.

The copolymer of Comparative Example C1 only uses the monomer represented by Formula (1) of the present disclosure for self-polymerization without using the monomer represented by Formula (2) of the present disclosure, the copolymer of Comparative Example C2 uses other phosphorus-containing compound which contains vinyl group and the monomer represented by Formula (1) of the present disclosure for polymerization without using the monomer represented by Formula (2) of the present disclosure, and the copolymer of Comparative Example C3 uses the monomer only including single vinyl group for polymerization without using the monomer represented by Formula (1) of the present disclosure. The samples of each of Comparative Examples C1 to C3 cannot achieve the following properties: a dissipation factor of less than or equal to 0.0030, a copper foil peeling strength of greater than or equal to 3.00 lb/in, a flame retardancy of V-0, and an X-axis coefficient of thermal expansion of less than or equal to 14.00 ppm/° C.

Comparative Example C4 uses the uncopolymerized monomer represented by Formula (1) and the uncopolymerized monomer represented by Formula (2), but do not use the copolymer formed by the monomer represented by Formula (1) of the present disclosure and the monomer represented by Formula (2) of the present disclosure. Therefore, the sample of Comparative Example C4 cannot achieve the following properties: a dissipation factor of less than or equal to 0.0030, a copper foil peeling strength of greater than or equal to 3.00 lb/in, a flame retardancy of V-0, and an X-axis coefficient of thermal expansion of less than or equal to 14.00 ppm/° C.

Comparative Example C5 uses 15 parts by weight of the copolymer, and Comparative Example C6 uses 70 parts by weight of the copolymer. The amount of copolymer of Comparative Examples C5 and C6 falls outside the range of 25 to 50 parts by weight. Therefore, the samples of each of Comparative Examples C5 and C6 cannot achieve the following properties: a dissipation factor of less than or equal to 0.0030, a copper foil peeling strength of greater than or equal to 3.00 lb/in, a flame retardancy of V-0, and an X-axis coefficient of thermal expansion of less than or equal to 14.00 ppm/° C.

In summary, the article, such as a prepreg, a resin film, a laminate, or a printed circuit board, made from the resin composition of the exemplary embodiment of the present disclosure has an excellent performance in at least one of the dissipation factor, the copper foil peeling strength, the flame retardancy and the X-axis coefficient of thermal expansion. Therefore, the article can be served as a high-performance laminate that satisfies the comprehensive demands.

What is claimed is:

1. A resin composition, comprising:
a vinyl group-containing resin; and
a phosphorus-containing copolymer, polymerized from a monomer represented by Formula (1) and a monomer represented by Formula (2); 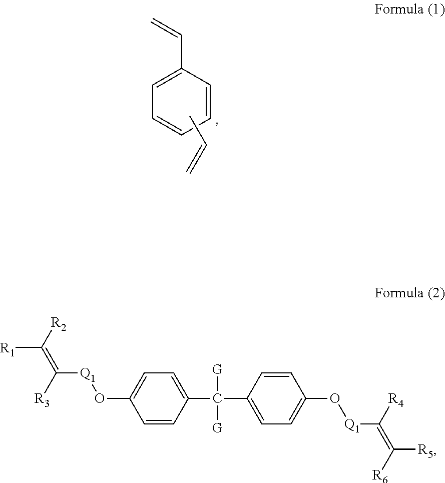
wherein each of R₁ to R₆ is independently selected from a hydrogen or a C1-C3 alkyl group;
wherein each G independently represents any one of a group represented by Formula (3) or a group represented by Formula (4) which is a monovalent phosphorus-containing functional group; 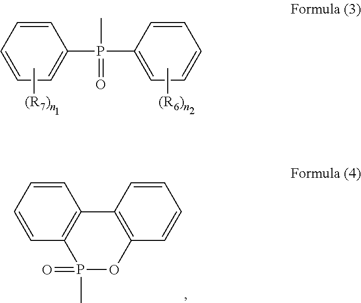
wherein each of R₇ to R₈ is independently a C1-C3 alkyl group, and each of n₁ to n₂ is independently an integer of 0 to 3;
wherein each Q₁ independently represents any one of —CO— or *—CH₂—C₆H₄-which is a divalent functional group, and a symbol “*” represents a binding site which binds to an oxygen atom.

2. The resin composition of claim 1, wherein a molar ratio of the monomer represented by Formula (1) to the monomer represented by Formula (2) is 1:7 to 3:7.

3. The resin composition of claim 1, wherein a weight average molecular weight of the phosphorus-containing copolymer is 2,000 to 4,000.

4. The resin composition of claim 1, wherein the resin composition comprises 100 parts by weight of the vinyl group-containing resin and 25 to 50 parts by weight of the phosphorus-containing copolymer.

5. The resin composition of claim 1, wherein the vinyl group-containing resin comprises: a vinyl group-containing polyphenylene ether resin, a maleimide resin, an ethylene propylene diene rubber, a compound represented by Formula (5), a styrene-butadiene copolymer, a polybutadiene, a diene group-containing fluorene compound, a hydrogenated polybutadiene resin terminated with divinylbenzene, or a combination thereof, 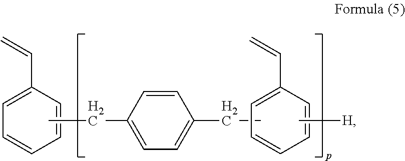
wherein p is an integer of 1 to 20.

6. The resin composition of claim 1, further comprising a compound represented by Formula (6):

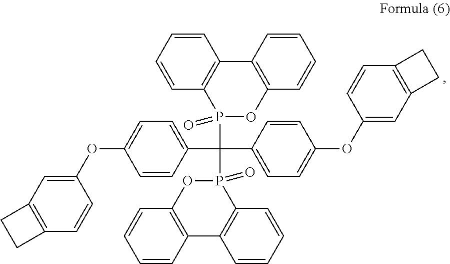 [SMILES: O=P1(C(c2ccc(Oc3ccc4c(c3)CC4)cc2)(c2ccc(Oc3ccc4c(c3)CC4)cc2)P2(=O)Oc3ccccc3-c3ccccc32)Oc2ccccc2-c2ccccc21]

7. The resin composition of claim 6, wherein the resin composition comprises 100 parts by weight of the vinyl group-containing resin and 15 to 25 parts by weight of the compound represented by Formula (6).

8. The resin composition of claim 1, further comprising an inorganic filler, a curing accelerator, a flame retardant, a polymerization inhibitor, a solvent, a silane coupling agent, a coloring agent, a toughening agent, or a combination thereof.

9. An article made from the resin composition of claim 1, comprising a prepreg, a resin film, a laminate, or a printed circuit board.

10. The article of claim 9, having at least one of the following properties:
a dissipation factor at 10 Hz as measured by reference to JIS C2565 of less than or equal to 0.0030;
a copper foil peeling strength as measured by reference to IPC-TM-650 2.4.8 of greater than or equal to 3.00 lb/in;
a flame retardancy as measured by reference to UL94 rating of V-0; and
an X-axis coefficient of thermal expansion as measured by reference to IPC-TM-650 2.4.24.5 of less than or equal to 14.00 ppm/° C.
